(19) United States
(12) Patent Application Publication
(10) Pub. No.: US 2015/0187909 A1
(43) Pub. Date: Jul. 2, 2015

(54) METHODS FOR FABRICATING MULTIPLE-GATE INTEGRATED CIRCUITS

(71) Applicant: GLOBAL FOUNDRIES, Inc., Grand Cayman (KY)

(72) Inventors: Ran Yan, Dresden (DE); Alban Zaka, Dresden (DE); Jan Hoentschel, Dresden (DE); LIN Kun-Hsien, Dresden (DE)

(73) Assignee: GLOBAL FOUNDRIES, Inc., Grand Cayman (KY)

(21) Appl. No.: 14/144,062

(22) Filed: Dec. 30, 2013

(51) Int. Cl. H01L 29/66; H01L 21/3105; H01L 21/02; H01L 21/311; H01L 21/762

(52) U.S. Cl. CPC H01L 29/66484; H01L 29/66795; H01L 21/31105; H01L 21/76264; H01L 21/0228; H01L 21/31056

(57) ABSTRACT

A method for fabricating an integrated circuit includes providing a silicon semiconductor substrate including a single-crystal crystallography, removing a portion of the semiconductor substrate to form a fin structure, the fin structure being defined by adjacent trenches formed within the semiconductor substrate, and forming an insulating material in the trenches, the insulating material covering a first portion of the fin and leaving a second portion of the fin exposed. The method further includes applying a wet etchant to the second portion of the fin, the wet etchant including an etching chemistry that selectively etches the fin against a <111> crystallographic orientation of the single-crystal silicon.

### TECHNICAL FIELD

The present disclosure generally relates to methods for fabricating integrated circuits. More particularly, the present disclosure relates to methods for fabricating multiple-gate integrated circuit structures, such as omega (Q)-gate integrated circuit structures and gate-all-around (GAA) integrated circuit structures.

### BACKGROUND

The majority of present day integrated circuits are implemented by using a plurality of interconnected field effect transistors (FETs), also called metal oxide semiconductor field effect transistors (MOSFETs), or simply MOS transistors. A typical MOS transistor includes a gate electrode as a control electrode formed over a semiconductive substrate, and spaced apart source and drain electrodes within the substrate between which a current can flow. A control voltage applied to the gate electrode controls the flow of current through a channel in the semiconductive substrate between the source and drain electrodes. Dielectric materials, such as silicon dioxide, are commonly employed to electrically separate the various gate electrodes in the integrated circuit.

The reduction in the size of MOSFETs has provided continued improvement in speed performance, circuit density, and cost per unit function over the past few decades. As the gate length of the conventional bulk MOSFET is reduced, however, the source and drain electrodes increasingly interact with the channel and gain influence on the channel potential. Consequently, a transistor with a short gate length suffers from problems related to the inability of the gate electrode to substantially control the on and off states of the channel. Phenomena such as reduced gate control associated with transistors with short channel lengths are termed “short-channel effects.” Increased substrate doping concentration, reduced gate oxide thickness, and shallow source/drain junctions are ways to suppress short-channel effects. However, for device scaling into the sub-50 nanometer (nm) regime, the requirements for doping concentration, gate oxide thickness, and source/drain doping profiles become increasingly difficult to meet.

For device scaling into the sub-50-nm regime, one approach to controlling short-channel effects is to use an alternative transistor structure with more than one gate, i.e. a multiple-gate transistor. A prior art multiple-gate transistor 10 is shown in top view in FIG. 1. Further, as shown in FIGS. 2A-2C (which illustrate various prior art multiple-gate transistors in cross-section, as will be described in greater detail below), the structure includes a silicon fin 12 overlying an insulator layer 14, which overlies a substrate 22. As used in the present disclosure, the term “overlie” is used to refer to a layer or device that is disposed vertically on another layer or device such that the two are in physical contact or over another layer or device (possible with one or more intermediate layers or devices thereinbetween) when the integrated circuit is oriented such that the semiconductor substrate is below the MOSFETs. A gate dielectric 20 overlies and covers a portion of the silicon fin 12, and a gate electrode 16 straddles across the silicon fin 12. The gate dielectric 20 isolates the gate electrode 16 from the silicon fin 12.

Examples of the multiple-gate transistor include the double-gate transistor, triple-gate transistor, omega transistor (Q-FET), and the surround-gate or gate-all-around (GAA) transistor. These multiple-gate transistor structures extend the scalability of CMOS technology beyond the limitations of the conventional MOSFET. The introduction of additional gates improves the capacitance coupling between the gates and the channel, increases the control of the channel potential by the gate, helps suppress short channel effects, and prolongs scalability of the MOS transistor.

A prior art example of the above-noted double-gate transistor is illustrated in the cross-sectional view of FIG. 2A. The double-gate transistor has a gate electrode 16 that straddles across the channel of the silicon fin 12, thus forming a double-gate structure. There are two gates, one on each sidewall 18 of the silicon fin 12. In this prior art example, the transistor channel includes the silicon fin 12, which is defined using an etchant mask 24 and formed on the insulator layer 14. Gate oxidation is performed, followed by gate deposition and gate patterning to form a double-gate structure overlying the sides of the fin.

Another example of the multiple-gate transistor is the triple-gate transistor. A cross-sectional view of a triple-gate transistor structure is provided in FIG. 2B. The triple-gate transistor structure has a gate electrode 16 that forms three gates: one gate on a top surface 26 of the silicon fin 12, and two gates on the sidewalls 18 of the silicon fin 12. The triple-gate transistor achieves better gate control than the double-gate transistor because it has one more gate on the top surface 26 of the silicon fin 12.

The triple-gate transistor structure may be modified for improved gate control, as illustrated in FIG. 2C. Such a structure is known as an Omega (Ω) field-effect transistor (FET), or simply omega-FET, since the gate electrode 16 has an omega-shape in its cross-sectional view. The encroachment of the gate electrode 16 under the semiconductor fin 12 forms an omega-shaped gate structure. The omega-FET has a top gate (adjacent surface 26), two sidewall gates (adjacent surfaces 18), and gate extensions or encroachments 28 under the fin 12. The omega-FET is therefore a field effect transistor with a gate that almost wraps around the fin. In fact, the longer the gate extension, i.e., the greater the extent of the encroachment E, the more the structure approaches or resembles a gate-all-around structure. The encroachment of the gate electrode 16 under the silicon fin 12 helps to shield the channel from electric field lines from the drain and improves gate-to-channel controllability, thus improving short-channel performance.

While, as noted above, some fabrication methods are known for multiple-gate structures using various additional patterning/etching steps, these fabrication methods are expensive to implement, due to the additional patterning/etching steps required, and are also subject to additional process variability for the same reasons. Lacking in the prior art are simplified methods for fabricating multiple-gate structures that are based on, for example, existing three-dimensional process flows such as conventional fin-FET fabrication flows.

Accordingly, it is desirable to provide improved methods for fabricating multiple-gate integrated circuits. Additionally, it is desirable to integrate such fabrication methods into existing process flow for the purposes of reducing fabrication costs and reducing process variability. Furthermore, other desirable features and characteristics of the present disclosure will become apparent from the subsequent detailed description and the appended claims, taken in conjunction with the drawings and the foregoing technical field and background of this disclosure.

### BRIEF SUMMARY

Various exemplary methods for fabricating multiple-gate integrated circuits are provided herein. In one exemplary embodiment, a method for fabricating an integrated circuit includes providing a silicon semiconductor substrate including a single-crystal crystallography, removing a portion of the semiconductor substrate to form a fin structure, the fin structure being defined by adjacent trenches formed within the semiconductor substrate, and forming an insulating material in the trenches, the insulating material covering a first portion of the fin and leaving a second portion of the fin exposed. The method further includes applying a wet etchant to the second portion of the fin, the wet etchant including an etching chemistry that selectively etches the fin against a <111> crystallographic orientation of the single-crystal silicon.

In another exemplary embodiment, a method for fabricating an integrated circuit includes providing a silicon semiconductor substrate having a single-crystal crystallography, patterning a hard mask layer over a first portion of the semiconductor substrate, while leaving a second portion of the semiconductor substrate exposed, and etching the exposed second portion of the semiconductor substrate to form a plurality of fin structures underneath the first portion, the fin structures being defined by etched trenches formed as a result of etching the exposed second portion. The method further includes depositing an insulating material into the etched trenches to a first height along the fin structures, the first height being less than a total height of the fin structures, thereby covering a first portion of the fin structures below the first height and leaving a second portion of the fin structures exposed above the first height, wherein a ratio of a height of the fin structures above the first height to a fin width is greater than about 1.41 and applying a wet etchant having a crystallographically-anisotropic etch behavior to the second portion of the fin structures, the wet etchant including an etching chemistry that selectively etches the fin structures against a <111> crystallographic orientation of the single-crystal silicon, wherein applying the wet etchant is performed for a period of time sufficient to form through-openings in the fin structures, thereby forming a plurality of gate-all-around structures. Still further, the method includes depositing a gate insulator material and a gate electrode material over the gate-all-around structures and etching the gate insulator material and the gate electrode material to form a plurality of gate-all-around multiple-gate electrode structures.

In yet another exemplary embodiment, a method for fabricating an integrated circuit includes providing a silicon semiconductor substrate including a single-crystal crystallography, patterning a hard mask layer over a first portion of the semiconductor substrate, while leaving a second portion of the semiconductor substrate exposed, and etching the exposed second portion of the semiconductor substrate to form a plurality of fin structures underneath the first portion, the fin structures being defined by etched trenches formed as a result of etching the exposed second portion. Further, the method includes depositing an insulating material into the etched trenches to a first height along the fin structures, the first height being less than a total height of the fin structures, thereby covering a first portion of the fin structures and leaving a second portion of the fin structures exposed and applying a wet etchant having a crystallographically-anisotropic etch behavior to the second portion of the fin structures, the wet etchant including an etching chemistry that selectively etches the fin structures against a <111> crystallographic orientation of the single-crystal silicon to form a cavity in the fin structures, wherein, if a ratio of a height of the second portion of the fin structures to a fin width is greater than about 1.41, applying the wet etchant is performed for a period of time insufficient to form through-openings in the fin structures, thereby forming a plurality of omega-gate structures. Still further, the method includes depositing a gate insulator material and a gate electrode material over the omega-gate structures and etching the gate insulator material and the gate electrode material to form a plurality of omega-gate multiple-gate electrode structures.

### BRIEF DESCRIPTION OF THE DRAWINGS

The various embodiments will hereinafter be described in conjunction with the following drawing figures, wherein like numerals denote like elements, and wherein:

FIG. 1 is a top view illustrating a multiple-gate transistor known in the prior art;

FIG. 2A is a cross-sectional view of a double-gate transistor known in the prior art;

FIG. 2B is a cross-sectional view of a triple-gate transistor known in the prior art;

FIG. 2C is a modified structure of the triple-gate transistor shown in FIG. 2B;

FIGS. 3A-3C illustrate, in cross section, integrated circuit structures and methods for fabricating integrated circuits in accordance with various embodiments of the present disclosure;

FIGS. 4A-4C illustrate, in cross section, additional integrated circuit structures in accordance with additional process steps of the methods for fabricating integrated circuits illustrated in FIGS. 3A-3C;

FIG. 5A illustrates, in cross section, an integrated circuit structure and methods for fabricating integrated circuit structures in accordance with another exemplary embodiment of the present disclosure; and

FIG. 5B illustrates, in cross section, an expanded view of a fin cavity formed in accordance with various embodiments of the present disclosure. detailed description.

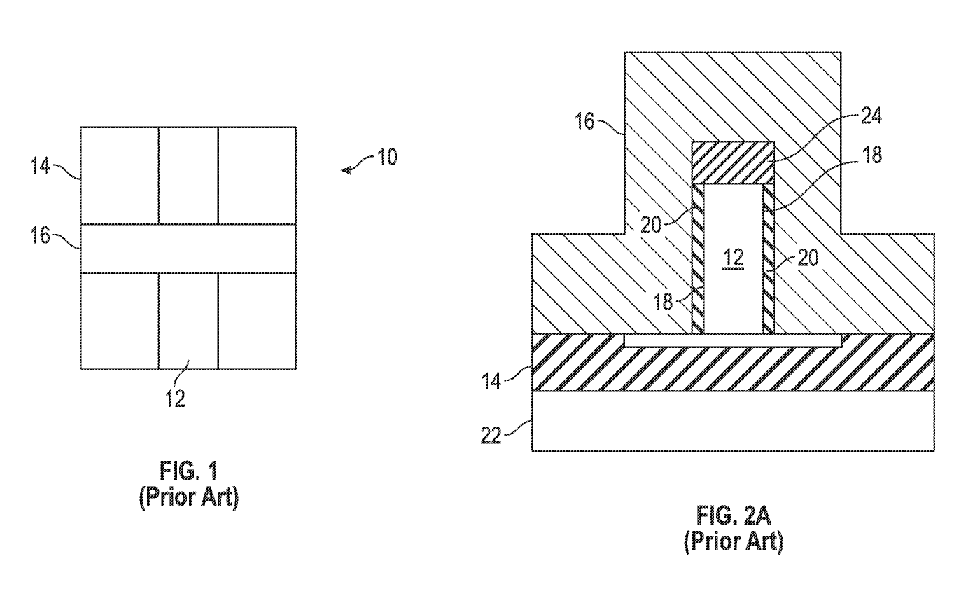

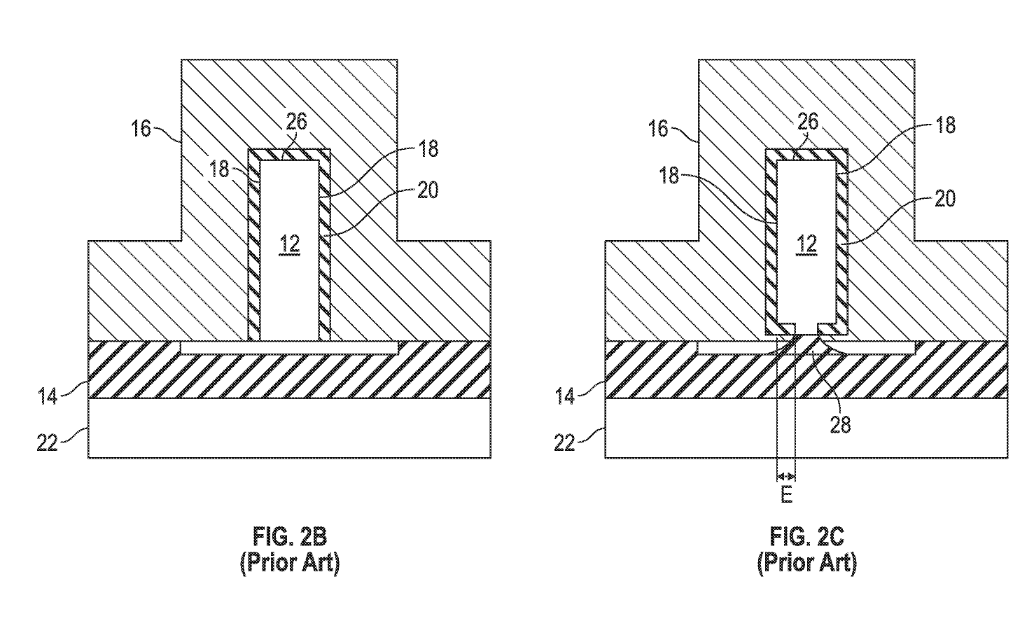

The following detailed description is merely illustrative in nature and is not intended to limit the embodiments of the subject matter or the application and uses of such embodiments. Furthermore, there is no intention to be bound by any expressed or implied theory presented in the preceding technical field, background, brief summary or the following

### DETAILED DESCRIPTION

Embodiments of the present disclosure relate to methods for fabricating multiple-gate integrated circuit structures, such as omega (Ω)-gate structures and gate-all-around (GAA) structures. The described embodiments employ an additional anisotropic wet etch step in a fin-FET fabrication flow to produce the desired gate structure. In this manner, additional patterning steps are not required to produce the multiple-gate structure, thus reducing fabrication costs and process variability.

Conventional techniques related to semiconductor device fabrication are well known and, so for the sake of brevity, many such steps may not be described in detail herein. Moreover, the various tasks and process steps described herein may be incorporated into a more comprehensive procedure or process having additional steps or functionality not described in detail herein. In particular, various steps in the manufacture of semiconductor based transistors are well known and so, in the interest of brevity, many conventional steps will only be mentioned briefly herein or will be omitted entirely without providing the well-known process details.

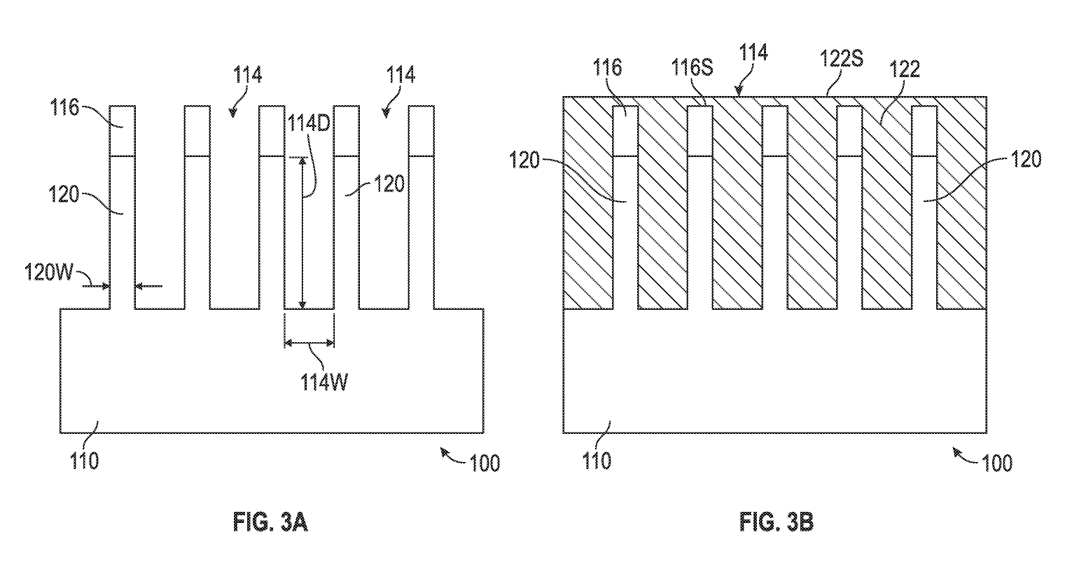

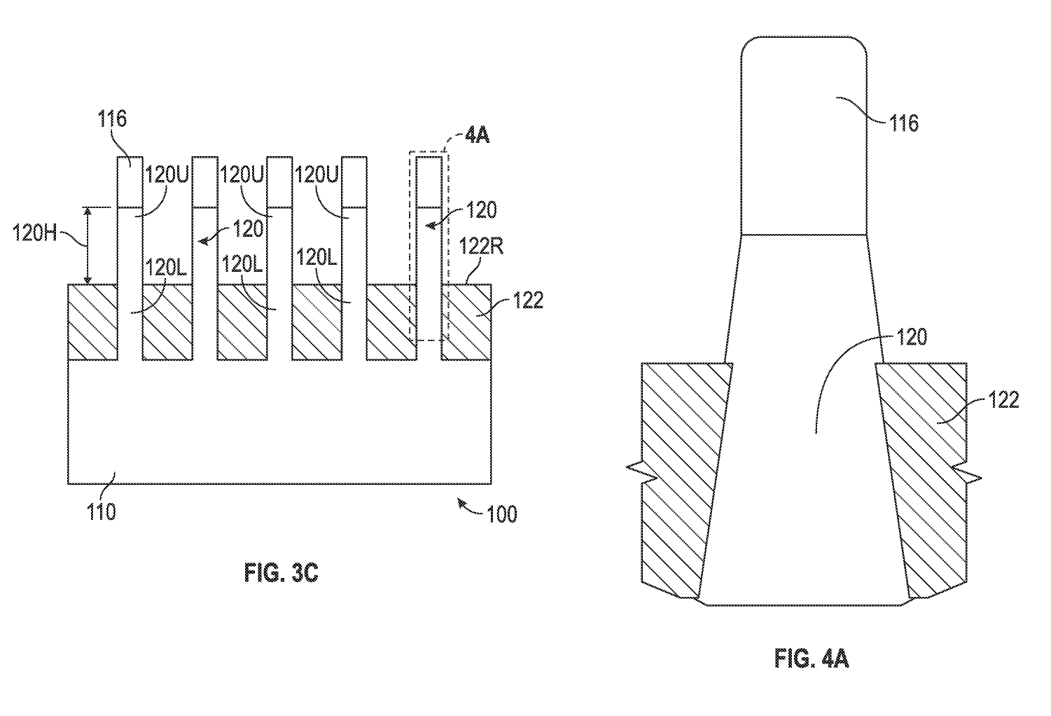

FIG. 3A is a simplified view of an illustrative FinFET semiconductor device 100 at an early stage of manufacturing that is formed above a semiconducting substrate 110. In contrast to traditional planar (MOSFETs), which are fabricated using conventional lithographic fabrication methods, non-planar MOSFETs incorporate various vertical transistor structures, and typically include two or more gate structures formed in parallel. One such semiconductor device is the “FinFET,” which takes its name from the multiple thin silicon “fins” that are used to form the respective gate channels, and which are typically on the order of tens of nanometers in width. The substrate 110 may have a variety of configurations, such as the depicted bulk silicon configuration having a defined crystallography (i.e., a single-crystal silicon). For instance, the substrate 110 may represent a semiconductor material, for instance, a silicon material in combination with an appropriate silicon-based layer in and above which transistor elements may be formed. In other cases, a buried insulating layer (not shown) may be formed between the substrate material and the corresponding “active” silicon-based material layer, thereby providing a silicon-on-insulator (SOI) configuration. The substrate 101 may also be made of semiconductive materials other than silicon.

At the point of fabrication depicted in FIG. 3A, a patterned mask layer 116, such as a patterned hard mask layer, has been formed above the substrate 110 using known photolithography and etching techniques. The patterned mask layer 116 is intended to be representative in nature as it could include a variety of materials, such as, for example, a photoresist material, silicon nitride, silicon oxynitride, silicon dioxide, etc. The patterned mask layer 116 may be formed by performing a variety of known processing techniques, such as a chemical vapor deposition (CVD) process, an atomic layer deposition (ALD) process, or plasma enhanced versions of such processes, and the thickness of such a layer 116 may vary depending upon the particular application. In one illustrative embodiment, the patterned mask layer 116 is a hard mask layer of silicon nitride that is initially formed by performing a CVD process and thereafter patterned using known sidewall image transfer techniques and/or photolithographic techniques combined with performing known etching techniques.

With continuing reference to FIG. 3A, an etching process, such as a dry or wet etching process, is performed on the substrate 110 using the patterned mask layer 116 to form a plurality of trenches 114. This etching process results in the definition of a plurality of fins 120. The overall size, shape, and configuration of the trenches 114 and fins 120 may vary depending on the particular application. The depth, indicated by double-headed arrow 114D, and width, indicated by double-headed arrow 114W, of the trenches 114 may vary depending upon the particular application. In one illustrative embodiment, the depth 114D of the trenches 114 may be from about 20 nm to about 150 nm and the width 114W of the trenches 114 may be from about 5 nm to about 50 nm. In some embodiments, the fins 120 may have a width 120W from about 5 nm to about 30 nm.

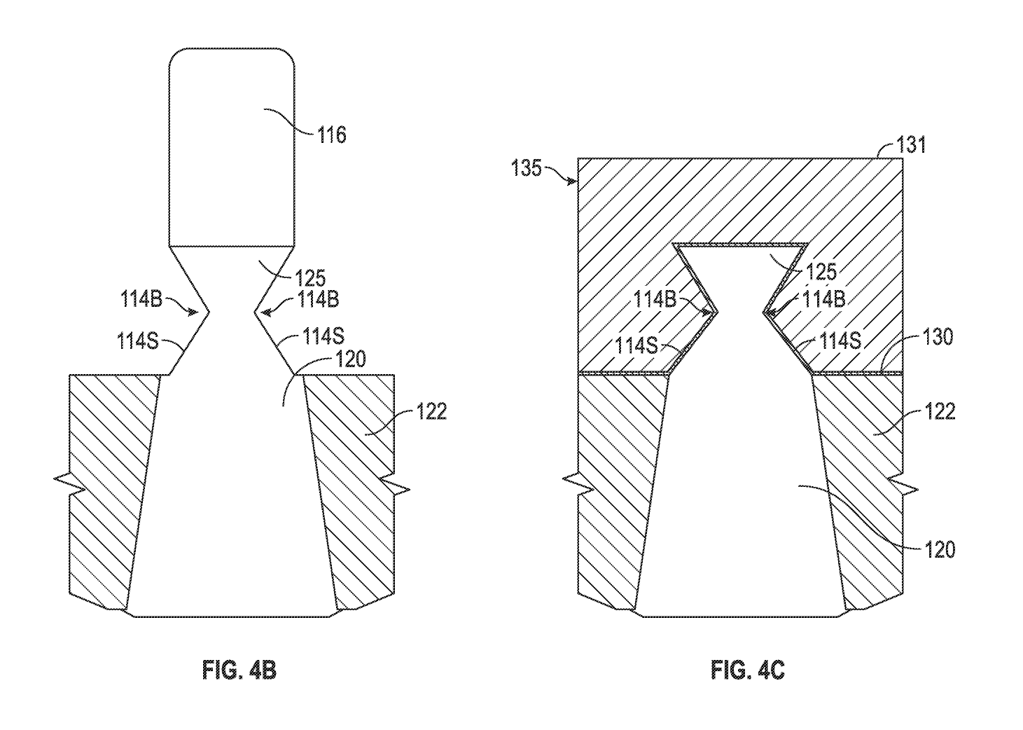

In the illustrative example depicted in FIG. 3A, the trenches 114 and fins 120 are all of a uniform size and shape. However, such uniformity in the size and shape of the trenches 114 and the fins 120 is not required in the practice of the embodiments disclosed herein. In the example depicted herein, the trenches 114 are formed by performing an anisotropic etching process that results in the trenches 114 having a schematically depicted, generally rectangular configuration. The sidewalls of the trenches 114 may be somewhat outwardly tapered, a feature that is shown in greater detail in the expanded illustrations in FIGS. 4A-4C, described in greater detail below. To the extent the trenches 114 are formed by a wet etching process, the trenches 114 may tend to have a more rounded configuration or non-linear configuration as compared to the generally rectangular configuration of the trenches 114 that are formed by an anisotropic etching process. Thus, the size and configuration of the trenches 114, and the manner in which they are made, should not be considered a limitation of the present disclosure.

Thereafter, as shown in FIG. 3B, a layer of insulating material 122 is formed in the trenches 114 of the device 100. The layer of insulating material 122 may include, for example, silicon dioxide, and it may be formed by a variety of techniques, e.g., CVD, spin-coating, etc. In one illustrative embodiment, the layer of insulating material 122 may be a flowable silicon oxide material that is formed by a CVD or spin-on process. In the example depicted in FIG. 3B, a surface 122S of the layer of insulating material 122 is the “as-deposited” surface of the layer 122. In this example, the surface 122S of the layer of insulating material 122 may be positioned slightly above an upper surface 116S of the mask layer 116. Alternatively, if desired, a chemical mechanical polishing (CMP) process may be performed to planarize the surface 122S using the mask layer 116 as a polish-stop layer. After such a CMP process, the surface 122S of the layer of insulating material 122 would be substantially level with the surface 116S of the mask layer 116.

FIG. 3C depicts the device 100 after the layer of insulating material 122 has been recessed, which is illustrated as having a recessed surface 122R. The layer of insulating material 122 covers a lower portion of the fins 120L while exposing an upper portion of the fins 120U. In one example, starting with the device depicted in FIG. 3B, the layer of insulating material 122 may be recessed by an etching process on the as-deposited layer of insulating material 122. Alternatively, a CMP process may be performed on the layer of insulating material 122 prior to performing such an etching process. The recessed layer of insulating material 122 defines a fin height, indicated by double-headed arrow 120H, of the fins 120. The fin height 120H may vary depending upon the particular application and, in one illustrative embodiment, may be from about 5 nm to about 50 nm.

For ease of illustration, the description of the exemplary method continues with reference to FIGS. 4A-4C, which provide expanded views of the fins 120, upon which an anisotropic etching process is performed to form the multiple-gate integrated circuit structures of the present disclosure, as described more fully below. Thus, while an expanded view is provided, it will be appreciated that there is no change in the integrated circuit structure, except as specifically provided with respect to each respective Figure. For example, FIG. 4A shows an expanded view of FIG. 3C, focusing on an exemplary fin 120 and the insulating material 122 along a portion of the sidewalls thereof, and the hard mask layer 116 formed thereover. As noted above, in the expanded view of FIG. 4A, the tapering of the fin 120 becomes apparent.

With reference now to FIG. 4B, the Figure schematically illustrates the silicon fin 120 in a further advanced manufacturing stage, in which cavities 114B may be formed on the basis of an anisotropic wet etch process. In some illustrative embodiments, the etch process may be performed on the basis of a wet chemical etch recipe having a crystallographically-anisotropic etch behavior when applied to silicon. That is, the chemical etch recipe is provided such that the etch rate depends on the crystallographic orientation of crystal planes of the silicon. For example, specific etch recipes may be provided in which <111> crystallographic planes may act as etch stop planes, thereby obtaining a self-restricting lateral etch rate for a standard crystallographic configuration of the material. In this case, the cavities 114B may have inclined surface areas 114S along the <111> crystallographic planes that may thus restrict the lateral etch rate and thus define the degree of under-etching of the fin structure 120. Consequently, for given lateral dimensions of the fin structure 120 (i.e., width and height), cavities 114B having a well-defined degree of under-etching may be provided, for instance by controlling the etch using the crystallographically-anisotropic etch chemistry.

Several such anisotropic wet etchants may be provided for etching silicon in the manner noted above, substantially all of them including hot aqueous caustic solutions. For instance, potassium hydroxide (KOH) displays an etch rate selectivity 400 times higher in <100> crystal directions than in <111> directions. EDP (an aqueous solution of ethylene diamine and pyrocatechol), displays a <100>/<111> selectivity of 17 times, does not etch silicon dioxide as KOH does, and also displays high selectivity between lightly doped and heavily boron-doped (p-type) silicon. Tetramethylammonium hydroxide (TMAH) presents an alternative to EDP, with a 37 times selectivity between <100> and <111> planes in silicon. Thus, in accordance with the present disclosure, in one exemplary embodiment, TMAH may be used for anisotropically etching the silicon fins 120 with a high degree of selectivity with respect to silicon dioxide (e.g., insulating material 122), silicon nitride (e.g., mask layer 116) and the like. Thus, the etch is restricted to the silicon fins to form the illustrated cavities 114B. In other illustrative embodiments, the cavities 114B may be formed with a degree of under-etching by applying an isotropic etch chemistry, for instance a plasma assisted etch chemistry or a wet chemical etch chemistry, wherein the lateral degree of under-etching may be determined by controlling the total etch time. Using this controlled etching, a multiple-gate structure, in this instance an omega-gate structure, may be formed.

Thereafter, the illustrative multiple-gate integrated circuit device 100 may be subjected to further fabrication processes using conventional fabrication techniques. For example, FIG. 4C depicts the fin 120 after one or more etching processes have been performed to remove the mask layer 116 and an illustrative gate structure 135 has been formed for the device 100. In one illustrative embodiment, the schematically depicted gate structure 135 includes a gate insulation layer 130 and a gate electrode 131. The gate insulation layer 130 may include a variety of different materials, such as, for example, silicon dioxide, a so-called high-k (i.e., having a dielectric constant greater than silicon dioxide, where “k” is the relative dielectric constant) insulation material, etc. Similarly, the gate electrode 131 may also be of a material such as polycrystalline silicon or amorphous silicon, or it may include one or more metal layers that act as the gate electrode 131, as is known in the art.

As will be recognized by those skilled in the art, the gate structure of the device 100 depicted in the drawings, i.e., the gate insulation layer 130 and the gate electrode 131, is intended to be representative in nature. In one illustrative embodiment, an oxidation process may be performed to form a gate insulation layer 130 formed of silicon dioxide. Thereafter, the gate electrode material 131 and a gate cap layer of material (not shown) may be deposited above the device 100 and the layers may be patterned using known photolithographic and etching techniques.

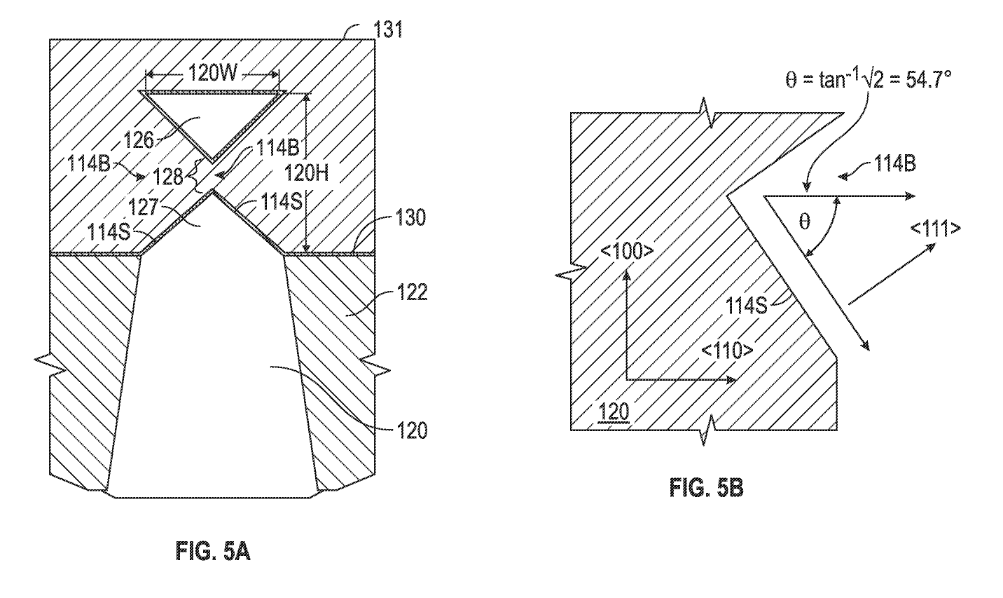

In an alternative embodiment as depicted in FIG. 5A, the controllable crystallographically-anisotropic etch process may be controlled so as to further etch against the <111> crystallographic planes 114S to form a through-opening 128 within fin 120, thereby leaving an upper, GAA fin portion 126 and a lower fin portion 127. As will be appreciated, the GAA fin portion 126 only extends for a given length along the semiconductive substrate, and as such it is supported at opposite ends thereof by the semiconductive substrate. The width 120W and final height 120H may be configured to allow sufficient height for the through-opening 128 to form upon sufficient etching. The height/width requirements to form the GAA structure are illustrated with respect to FIG. 5B, which provides an expanded view of a cavity 114B formed in silicon fin 120 during the above-described etching. As shown in FIG. 5B, the <111> crystallographic plane is at an angle of θ=tan⁻¹(2^{1/2})≈54.7° relative to a plane that is parallel to surface 112R, as shown by the angle θ in FIG. 5B. Thus, as long as the fin height 120H is more than tan(54.7°) (i.e., about 1.41) times the fin width 120W (and provided that the etch is performed for a sufficient length of time, which will depend on the actual fin dimensions and the etchant applied), it will be possible to form a GAA structure. In this manner, using this controlled etching, a multiple-gate structure, in this instance a gate-all-around gate structure, may be formed, as shown in FIG. 5A.

As such, it will be appreciated that, in accordance with embodiments of the present disclosure, in order to form an omega-gate structure, the fin dimensions are provided such that a ratio of the fin height 120H to the fin width 120W is less than about 1.41, or, the crystallographically-anisotropic wet etch is applied for a time period insufficient to etch entirely through the fin 120 (which, as noted above, will depend on the actual fin dimensions and the etchant applied). Conversely, in order to form a GAA structure, the fin dimensions are provided such that a ratio of the fin height 120H to the fin width 120W is greater than about 1.41, and, the crystallographically-anisotropic wet etch is applied for a time period sufficient to etch entirely through the fin 120 to form the through-opening 128.

Although not illustrated, with regard to any of the embodiments described above, the partially-formed multiple-gate integrated circuit is completed in a conventional manner by, for example, forming source and drain regions, providing electrical contacts to the source and drain regions and to the gate electrodes, depositing interlayer dielectrics, etching contact vias, filling the contact vias with conductive plugs, and the like as are well known to those of skill in the art of fabricating integrated circuits. Additional post-processing may include the formation of one or more metal layers (M1, M2, etc.) and interlayer dielectric layers therebetween to complete the various electrical connections in the integrated circuit. The present disclosure is not intended to exclude such further processing steps as are necessary to complete the fabrication of a functional integrated circuit, as are known in the art.

While at least one exemplary embodiment has been presented in the foregoing detailed description of the disclosure, it should be appreciated that a vast number of variations exist. It should also be appreciated that the exemplary embodiment or exemplary embodiments are only examples, and are not intended to limit the scope, applicability, or configuration of the disclosure in any way. Rather, the foregoing detailed description will provide those skilled in the art with a convenient road map for implementing an exemplary embodiment of the disclosure. It being understood that various changes may be made in the function and arrangement of elements described in an exemplary embodiment without departing from the scope of the disclosure as set forth in the appended claims.

What is claimed is:

1. A method for fabricating an integrated circuit comprising:
providing a silicon semiconductor substrate comprising a single-crystal crystallography;
removing a portion of the semiconductor substrate to form a fin structure, the fin structure being defined by adjacent trenches formed within the semiconductor substrate;
forming an insulating material in the trenches, the insulating material covering a first portion of the fin and leaving a second portion of the fin exposed; and
applying a wet etchant to the second portion of the fin, the wet etchant comprising an etching chemistry that selectively etches the fin against a <111> crystallographic orientation of the single-crystal silicon.

2. The method of claim 1, wherein providing the semiconductor substrate comprises providing a bulk silicon semiconductor substrate.

3. The method of claim 1, wherein providing the semiconductor substrate comprises providing a silicon-on-insulator semiconductor substrate.

4. The method of claim 1, wherein removing the portion of the semiconductor substrate comprises patterning a silicon nitride material layer.

5. The method of claim 1, wherein removing the portion of the semiconductor substrate comprises patterning a photoresist material layer.

6. The method of claim 1, wherein forming the insulating material comprises depositing a silicon oxide material.

7. The method of claim 6, wherein forming the insulating material comprises CVD-depositing a silicon oxide material.

8. The method of claim 1, wherein forming the insulating material comprises ALD-depositing a silicon oxide material.

9. The method of claim 1, wherein forming the insulating material comprises spin-on depositing a silicon oxide material.

10. The method of claim 1, further comprising planarizing the insulating material using chemical mechanical planarization.

11. The method of claim 1, wherein the second portion of the fin has a length of about 5 nm to about 50 nm.

12. The method of claim 1, wherein applying the wet etchant comprises applying an etchant having a crystallographically-anisotropic etch behavior.

13. The method of claim 12, wherein applying the wet etchant comprises applying a TMAH etchant.

14. The method of claim 1, further comprising depositing a gate insulator material and a gate electrode material over the fin and etching the gate insulator material and the gate electrode material to form a multiple gate electrode structure, wherein the multiple gate electrode structure is an omega-gate electrode structure.

15. The method of claim 14, wherein depositing the gate electrode material comprises depositing a polycrystalline silicon material, an amorphous silicon material, or a metallic material.

16. The method of claim 1, further comprising depositing a gate insulator material and a gate electrode material over the fin and etching the gate insulator material and the gate electrode material to form a multiple gate electrode structure, wherein the multiple gate electrode structure is a gate-all-around gate electrode structure.

17. The method of claim 16, wherein a ratio of a fin height to a fin width is greater than about 1.41.

18. The method of claim 16, wherein depositing the gate electrode material comprises depositing a polycrystalline silicon material, an amorphous silicon material, or a metallic material.

19. A method for fabricating an integrated circuit comprising:
providing a silicon semiconductor substrate comprising a single-crystal crystallography;
patterning a hard mask layer overlying a first portion of the semiconductor substrate, while leaving a second portion of the semiconductor substrate exposed;
etching the second portion of the semiconductor substrate to form a plurality of fin structures underneath the first portion, the fin structures being defined by trenches formed as a result of etching the exposed second portion;
depositing an insulating material into the etched trenches to a first height along the fin structures, the first height being less than a total height of the fin structures, thereby covering a first portion of the fin structures and leaving a second portion of the fin structures exposed, wherein a ratio of a height of the second portion of the fin structures to a fin width is greater than about 1.41;
applying a wet etchant having a crystallographically-anisotropic etch behavior to the second portion of the fin structures, the wet etchant comprising an etching chemistry that selectively etches the fin structures against a <111> crystallographic orientation of the single-crystal silicon, wherein applying the wet etchant is performed for a period of time sufficient to form through-openings in the fin structures; and
depositing a gate insulator material and a gate electrode material overlying the gate-all-around structures and etching the gate insulator material and the gate electrode material to form a plurality of gate-all-around multiple-gate electrode structures.

20. A method for fabricating an integrated circuit comprising:
providing a silicon semiconductor substrate comprising a single-crystal crystallography;
patterning a hard mask layer over a first portion of the semiconductor substrate, while leaving a second portion of the semiconductor substrate exposed;
etching the exposed second portion of the semiconductor substrate to form a plurality of fin structures underneath the first portion, the fin structures being defined by etched trenches formed as a result of etching the exposed second portion;
depositing an insulating material into the etched trenches to a first height along the fin structures, the first height being less than a total height of the fin structures, thereby covering a first portion of the fin structures and leaving a second portion of the fin structures exposed;
applying a wet etchant having a crystallographically-anisotropic etch behavior to the second portion of the fin structures, the wet etchant comprising an etching chemistry that selectively etches the fin structures against a <111> crystallographic orientation of the single-crystal silicon to form a cavity in the fin structures, wherein, if a ratio of a height of the second portion of the fin structures to a fin width is greater than about 1.41, applying the wet etchant is performed for a period of time insufficient to form through-openings in the fin structures, thereby forming a plurality of omega-gate structures; and
depositing a gate insulator material and a gate electrode material over the omega-gate structures and etching the gate insulator material and the gate electrode material to form a plurality of omega-gate multiple-gate electrode structures.
